(19) United States
(12) Patent Application Publication
(10) Pub. No.: US 2026/0324391 A1
(43) Pub. Date: Oct. 15, 2026

(54) Metallization Layer Spacing for Interconnect Structures

(71) Applicant: International Business Machines Corporation, Armonk, NY (US)

(72) Inventors: Atsushi Ogino, Fishkill, NY (US); Baozhen Li, South Burlington, VT (US); Matthew Stephen Angyal, Stormville, NY (US)

(21) Appl. No.: 19/174,297

(22) Filed: Apr. 9, 2025

(51) Int. Cl. H10W 20/42; H10W 20/00; H10W 20/41; H10W 20/48

(52) U.S. Cl. CPC H10W 20/42; H10W 20/084; H10W 20/427; H10W 20/48

(57) ABSTRACT

A semiconductor structure includes a first set of interconnected metal lines and a second set of interconnected metal lines. The semiconductor structure includes a first metallization layer including a first metal line in the first set of interconnected metal lines and a second metal line in the second set of interconnected metal lines. The semiconductor structure further includes a second metallization layer including a third metal line in the second set of interconnected metal lines, where the third metal line is disposed above the first metal line and the second metal line, and where a spacing between the first metal line and the third metal line is greater than a spacing between the second metal line and the third metal line.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments described herein provide techniques for forming interconnect structures with varying spacing between metallization layers.

In one embodiment, a semiconductor structure includes a first set of interconnected metal lines and a second set of interconnected metal lines. The semiconductor structure includes a first metallization layer including a first metal line in the first set of interconnected metal lines and a second metal line in the second set of interconnected metal lines. The semiconductor structure further includes a second metallization layer including a third metal line in the second set of interconnected metal lines, where the third metal line is disposed above the first metal line and the second metal line, and where a spacing between the first metal line and the third metal line is greater than a spacing between the second metal line and the third metal line.

In another embodiment, a semiconductor structure includes a first set of interconnected metal lines and a second set of interconnected metal lines. The semiconductor structure includes a first metallization layer including a first metal line in the first set of interconnected metal lines and a second metal line in the second set of interconnected metal lines. The semiconductor structure includes a second metallization layer including a third metal line in the second set of interconnected metal lines, where the third metal line is disposed above the first metal line and the second metal line. The semiconductor structure further includes an interlayer dielectric layer positioned between the first metallization layer and the second metallization layer, where a first portion of the interlayer dielectric layer above the first metal line is thicker than a second portion of the interlayer dielectric layer above the second metal line.

In another embodiment, a method includes forming a first metallization layer including a first metal line and a second metal line, depositing an etch stop layer over the first metallization layer, and selectively removing portions of the etch stop layer above the second metal line. The method further includes forming a second metallization layer including a third metal line, where a vertical spacing between the first metal line and the third metal line is greater than a vertical spacing between the second metal line and the third metal line, and where the first metal line corresponds to a first set of interconnected metal lines and the second metal line and third metal line correspond to a second set of interconnected metal lines.

These and other features and advantages of embodiments described herein will become more apparent from the accompanying drawings and the following detailed description.

### BRIEF DESCRIPTION OF THE DRAWINGS

FIG. 1 depicts a cross-sectional view of an interconnect structure at an intermediate state of a fabrication process, according to an illustrative embodiment.

FIG. 2 depicts a cross-sectional view of the interconnect structure following formation of a first photoresist (PR) layer, according to an illustrative embodiment.

FIG. 3 depicts a cross-sectional view of the interconnect structure following patterning of an etch stop layer and formation of an interlayer dielectric (ILD) layer and a hardmask (HM) layer, according to an illustrative embodiment.

FIG. 4 depicts a cross-sectional view of the interconnect structure following formation of a second PR layer, according to an illustrative embodiment.

FIG. 5 depicts a cross-sectional view of the interconnect structure following patterning of the HM layer, according to an illustrative embodiment.

FIG. 6 depicts a cross-sectional view of the interconnect structure following via patterning and a dual damascene etch, according to an illustrative embodiment.

FIG. 7 depicts a cross-sectional view of the interconnect structure following a metallization process, according to an illustrative embodiment.

FIG. 8 depicts a cross-sectional view of the interconnect structure following a planarization process, according to an illustrative embodiment.

FIGS. 9-11 depict cross-sectional views of an interconnect structure in accordance with an alternative process starting from FIG. 5, according to an illustrative embodiment.

FIG. 12A depicts a top view of an interconnect structure, indicating an X cross-section location on which the cross-sectional view of FIG. 12B is based.

FIG. 12B depicts a cross-sectional view of the interconnect structure corresponding to the line X in FIG. 12A, according to an illustrative embodiment.

### DETAILED DESCRIPTION

Illustrative embodiments may be described herein in the context of illustrative methods for forming interconnect structures with varying spacing between metallization layers, along with illustrative apparatus, systems and devices formed using such methods. However, it is to be understood that embodiments are not limited to the illustrative methods, apparatus, systems and devices but instead are more broadly applicable to other suitable methods, apparatus, systems and devices.

Semiconductor devices can include a plurality of circuits which form an integrated circuit fabricated on a substrate. A complex network of signal paths can be routed to connect the circuit elements distributed on the surface of the substrate. Efficient routing of these signals can include the formation of multilevel or multilayered schemes (e.g., single or dual damascene wiring structures) during the back-end-of-line (BEOL) phase of manufacturing. For example, semiconductor devices rely on a plurality of metallization layers or metal lines stacked on top of one another on the semiconductor substrate to provide electronic interconnections between integrated circuits on the substrate. A metallization layer may also be referred to as a BEOL metallization layer which could be disposed on a semiconductor material stack. Semiconductor contacts in a top layer in the semiconductor material stack are electrically connected to metal contacts and metal interconnects in a metallization layer disposed on the semiconductor material stack.

Generally, interconnects are structures that connect two or more circuit elements (such as transistors or power rails) together electrically. In addition to providing the electrical connection to the frontend devices (such as transistors), interconnects also go all the way back to the power delivery networks. Thus, interconnects and their surrounding support components are considered BEOL components. Lines and vias are important components of interconnect technology. Lines provide electrical connections within a single layer, and vias provide electrical connections between layers in a physical electronic circuit.

As technology continues to be scaled and transistors become smaller, increasingly tightly spaced interconnects are required to connect to them. Scaling interconnects pushes the boundaries of minimum widths, minimum spacings, and minimum pitches. However, these decreasing sizes and increasing densities introduce performance and reliability issues. In particular, critical dimensions refer to the sizes of electronic components that must be maintained to avoid unwanted impacts on the electrical properties of the device. Accordingly, the geometric properties of interconnect structures are limited not only by fabrication constraints but also by performance constraints.

Typically, intra-layer time-dependent dielectric breakdown (TDDB) reliability is controlled by increasing lateral spacing between adjacent metal lines within a given metallization layer to accommodate higher voltages. However, inter-layer TDDB between consecutive metallization layers (e.g., a first metallization layer (Mx) and a second metallization layer (Mx+1)) is constrained by via height, which cannot be easily controlled through design adjustments. Via height and ILD layer thickness between the metallization layers continues to decrease as technology scales to advanced nodes, which increases the risk for high-voltage circuits such as input/output (I/O) interfaces. This has prompted some foundries to restrict high-voltage applications in advanced processes due to the increased likelihood of inter-layer TDDB failures.

Embodiments described herein provide an interconnect structure that increases vertical spacing between consecutive metallization layers above regions where vertically overlapping metal lines operate at different voltage levels, compared to the vertical spacing of other regions (including regions where metal lines operate at the same voltage level). The increased vertical spacing allows thicker dielectric separation between metal lines operating at different voltage levels, while maintaining consistent via heights between the consecutive metallization layers regardless of the voltage levels. Such embodiments effectively improve the reliability and performance of semiconductor devices in high-voltage applications by reducing inter-layer TDDB risks without compromising compatibility with existing process flows, for example.

Detailed embodiments of interconnect structures and methods are disclosed herein. The method steps described below do not form a complete process flow for manufacturing integrated circuits, such as semiconductor devices. The present embodiments can be practiced in conjunction with the integrated circuit fabrication techniques currently used in the art and only so much of the commonly practiced process steps are included as are necessary for an understanding of the described embodiments. The figures represent cross-section portions of a semiconductor structure after fabrication and are not drawn to scale, but instead are drawn to illustrate the features of the described embodiments. Specific structural and functional details disclosed herein are not intended to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

References in the specification to “one embodiment”, “other embodiment”, “another embodiment”, “an embodiment”, etc., indicate that the embodiment described may include a particular feature, structure or characteristic, but every embodiment may not necessarily include the particular feature, structure or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. The terms “overlying”, “atop”, “over”, “on”, “positioned on” or “positioned atop” mean that a first element is present on a second element wherein intervening elements, such as an interface structure, may be present between the first element and the second element. The term “direct contact” means that a first element and a second element are connected without any intermediary conducting, insulating or semiconductor layers at the interface of the two elements.

It will be understood that, although the terms first, second, etc., may be used herein to describe various elements, these elements should not be limited by these terms. These terms are only used to distinguish one element from another element. Thus, a first element discussed below could be termed a second element without departing from the scope of the present concept.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element. Terms such as “thick”, “thickness”, “thin” or derivatives thereof may be used in place of “height” where indicated.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

In the interest of not obscuring the presentation of the embodiments of the present disclosure, in the following detailed description, some of the processing steps, materials, or operations that are known in the art may have been combined together for presentation and for illustration purposes and in some instances may not have been described in detail. Additionally, for brevity and maintaining a focus on distinctive features of elements of the present disclosure, description of previously discussed materials, processes, and structures may not be repeated with regard to subsequent Figures. In other instances, some processing steps or operations that are known may not be described. It should be understood that the following description is rather focused on the distinctive features or elements of the various embodiments of the present disclosure.

It is to be understood that the various layers, structures, and/or regions shown in the accompanying drawings are schematic illustrations that are not necessarily drawn to scale. In addition, for ease of explanation, one or more layers, structures, and regions of a type commonly used to form semiconductor devices or structures may not be explicitly shown in a given drawing. This does not imply that any layers, structures, and regions not explicitly shown are omitted from the actual semiconductor structures.

In general, the various processes used to form a semiconductor chip fall into four general categories, namely, film deposition, removal/etching, semiconductor doping, and patterning/lithography. Deposition is any process that grows, coats, or otherwise transfers a material onto the wafer. Available technologies include but are not limited to physical vapor deposition (“PVD”), chemical vapor deposition (“CVD”), electrochemical deposition (“ECD”), molecular beam epitaxy (“MBE”) and more recently, atomic layer deposition (“ALD”) among others. Another deposition technology is plasma enhanced chemical vapor deposition (“PECVD”), which is a process that uses the energy within the plasma to induce reactions at the wafer surface that would otherwise require higher temperatures associated with conventional CVD. Energetic ion bombardment during PECVD deposition can also improve the film’s electrical and mechanical properties.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. The patterns created by lithography or photolithography typically are used to define or protect selected surfaces and portions of the semiconductor structure during subsequent etch processes.

Removal is any process such as etching or chemical-mechanical planarization (“CMP”) that removes material from the wafer. Examples of etch processes include either wet (e.g., chemical) or dry etch processes. One example of a removal process or dry etch process is ion beam etching (“IBE”). In general, IBE (or milling) refers to a dry plasma etch method that utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry etch process is reactive ion etching (“RIE”). In general, RIE uses chemically reactive plasma to remove material deposited on wafers. High-energy ions from the RIE plasma attack the wafer surface and react with the surface material(s) to remove the surface material(s).

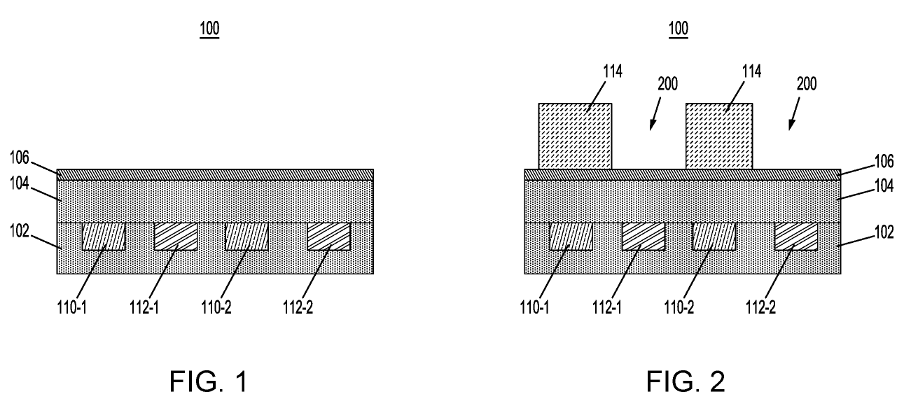

Referring now to the drawings, in which like numerals represent the same or similar elements, FIGS. 1-13 illustrate various processes for fabricating semiconductor structures with varying spacing between metallization layers. Note also that the semiconductor structures described herein can also be considered to be a semiconductor device and/or an integrated circuit, or some part thereof. For the purpose of clarity, some fabrication steps leading up to the production of the semiconductor structures as illustrated in FIGS. 1-13 are omitted. In other words, one or more well-known processing steps which are not illustrated but are well-known to those of ordinary skill in the art have not been included in the figures. This is not intended to be interpreted as a limitation of any particular embodiment, or illustration, or scope of the claims.

FIG. 1 depicts a cross-sectional view of an interconnect structure 100 at an intermediate state of a fabrication process. The interconnect structure 100 includes ILD layers 102 and 104, and an etch stop layer 106. A first metallization layer including metal lines 110-1 and 110-2 (collectively “metal lines 110”) and metal lines 112-1 and 112-2 (collectively “metal lines 112”) is formed in the ILD layer 102. According to an embodiment, a first set of interconnected metal lines including the metal lines 110 corresponds to a low-voltage domain and a second set of interconnected metal lines including the metal lines 112 corresponds to a high-voltage domain.

The term “voltage domain” as used herein generally refers to a specific region or area that operates at a particular voltage level. Voltage domains can be used to manage power consumption, noise, and signal integrity by separating parts of a semiconductor structure that require different voltage supplies. For example, a low-voltage domain might operate at a first voltage (e.g., below 1.0 V), and a high-voltage domain might operate at a different, higher voltage (e.g., above 1.8 V). The term “intersecting area” as used herein in the context of voltage domains generally refers to areas where metal lines from different voltage domains vertically overlap and come into proximity (e.g., less than 30nm) with one another. In some embodiments, the intersecting areas correspond to metal lines from consecutive metallization layers. At these intersecting areas, the vertical spacing between the metal lines must be carefully controlled to help prevent TDDB and ensure reliability.

In some embodiments, the interconnect structure 100 is formed on a substrate (not shown). For example, the substrate can include semiconductor materials such as silicon, germanium, silicon-germanium alloy, silicon carbon alloy, silicon-germanium-carbon alloy, gallium arsenide, indium arsenide, indium phosphide, III-V compound semiconductor materials, II-VI compound semiconductor materials, organic semiconductor materials, and other compound semiconductor materials. Typically, the semiconductor material includes silicon. The substrate can include a bulk semiconductor substrate or a semiconductor-on-insulator (SOI) substrate. In an illustrative embodiment, the substrate may already have pre-built structures (not shown), such as FETs, transistors, diodes, resistors, capacitors, inductors, interconnects, electrically programmable fuses, and/or combinations thereof.

The ILD layers 102 and 104 may include, for example, silicon oxide (SiOₓ), silicon oxycarbide (SiOC), silicon oxycarbonitride (SiOCN), or some other dielectric. A process such as CVD, ALD, or PVD can be used to deposit the ILD layers 102 and 104. Subsequently, a planarization process (e.g., CMP) can be carried out to planarize the upper surfaces of ILD layers 102 and 104. The etch stop layer 106 may include silicon nitride (SiN), silicon carbonitride (SiCN), silicon carbide (SiC), aluminum nitride (AlN), aluminum oxide (AlO), aluminum oxynitride (AlON), TiN, and/or SiOx.

In illustrative embodiments, the metal lines 110 and the metal lines 112 may include metallic liners (not shown), which can include a metal adhesion layer (e.g., TiN). The metal lines 110 and the metal lines 112 can be formed of any suitable conductive material, such as tungsten (W), aluminum (Al), copper (Cu), cobalt (Co), ruthenium (Ru), chromium (Cr), molybdenum (Mo), etc. The metal lines 110 and the metal lines 112 can be formed, for example, using a suitable deposition technique such as CVD, PECVD, ALD, PVD, molecular beam deposition (MBD), pulsed laser deposition (PLD), liquid source misted chemical deposition (LSMCD), sputtering, and/or plating, followed by a planarization process (e.g., CMP).

FIG. 2 shows the interconnect structure 100 following formation of a first PR layer 114. For example, the first PR layer 114 can be formed on a top surface of the etch stop layer 106 and can include a suitable light-sensitive polymer. Openings 200 are formed in the first PR layer 114 corresponding to intersecting areas of high-voltage and low-voltage domains, which correspond to the areas above the metal lines 112 in FIG. 2. Following the formation of the openings 200, portions of the etch stop layer 106 are exposed, as illustrated.

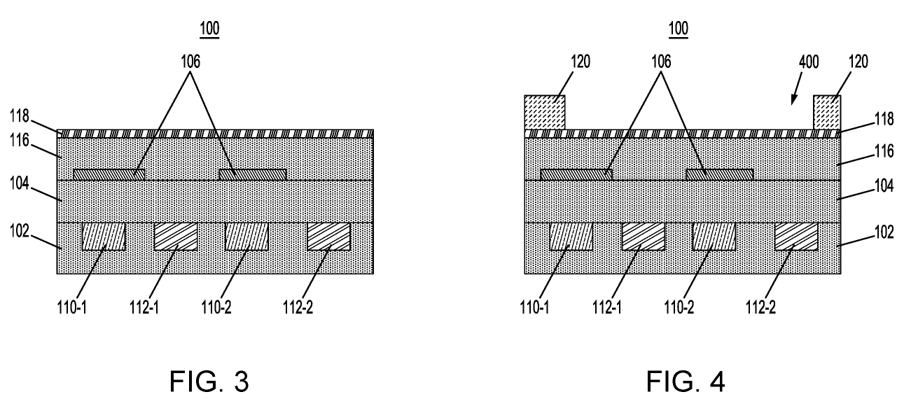

FIG. 3 shows a cross-sectional view of the interconnect structure 100 following removal of the exposed portions of the etch stop layer 106 and formation of an ILD layer 116 and a HM layer 118. The exposed portions of the etch stop layer 106 are removed using, for example, a dry etching process (e.g., RIE or IBE), a wet chemical etching process, or a combination of these etching processes. A planarization process (e.g., CMP) can be performed to remove the first PR layer 114.

The ILD layer 116 is formed by depositing dielectric material (for example, SiOₓ, SiOC, SiOCN or some other dielectric material) on the top surfaces of the ILD layer 104 and the remaining portions of etch stop layer 106. For example, the ILD layer 116 can be deposited using deposition techniques such as CVD, PECVD, radio frequency CVD (RFCVD), PVD, ALD, MBD, PLD, and/or LSMCD, followed by a planarization process, such as CMP.

The HM layer 118 is deposited on the ILD layer 116 using a suitable deposition technique such as PVD, ALD, CVD, etc. The HM layer 118 can be formed of a masking material, such as amorphous silicon or any other suitable masking material.

FIG. 4 shows the interconnect structure 100 following formation of a second PR layer 120. The second PR layer 120 can be formed on the HM layer 118 using similar techniques and materials as for the first PR layer 114. An opening 400 is formed in the second PR layer 120 using, for example, a dry etching process using RIE or IBE, a wet chemical etching process, or a combination of these etching processes. The opening 400 extends down to and exposes portions of the HM layer 118, as shown.

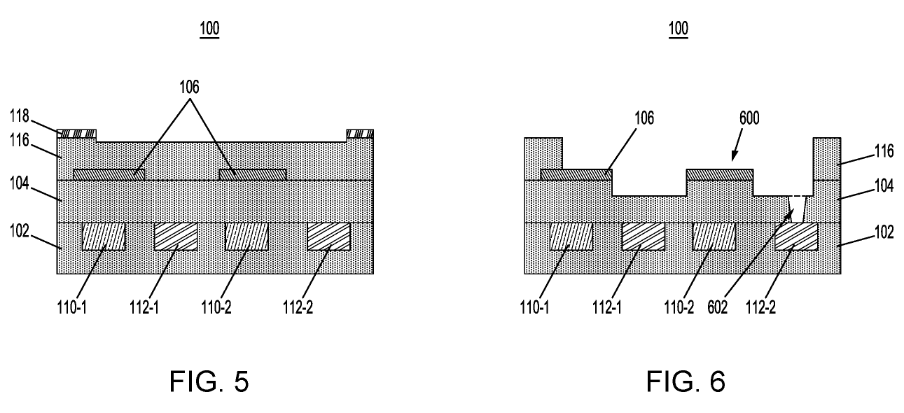

FIG. 5 shows a cross-sectional view of the interconnect structure 100 following patterning of the HM layer 118. The exposed portions of the HM layer 118 are removed, thereby exposing a portion of the ILD layer 116. The exposed portions of the HM layer 118 can be removed using, for example, a dry etching process using RIE or IBE, a wet chemical etching process, or a combination of these etching processes. The second PR layer 120 can be removed using a planarization process (e.g., CMP).

FIG. 6 shows a cross-sectional view of the interconnect structure 100 following an etching process to form a trench opening 600 and a via opening 602. For example, the etching process may correspond to a dual damascene etching process. For example, portions of the ILD layer 116 below and between the HM layer 118 can be removed down to the top surface of the etch stop layer 106. Further portions of ILD layer 116 and the ILD layer 104 that are adjacent to the etch stop layer 106 are also removed such that the trench opening 600 extends into the ILD layer 104, as shown. The portions of the ILD layer 104 corresponding to the via opening 602 can then be removed using one or more mask layers that fill in the trench opening 600. The portions of the ILD layers 104 and 116 corresponding to the trench opening 600 and the via opening 602 can be removed using one or more etching processes (e.g., a dry etching process, a wet chemical etching process, or a combination of these etching processes). The HM layer 118 is also removed using, for example, a planarization process. The dual damascene etching process enables simultaneous formation of a metal line 122 and a via 124, as shown in FIG. 8.

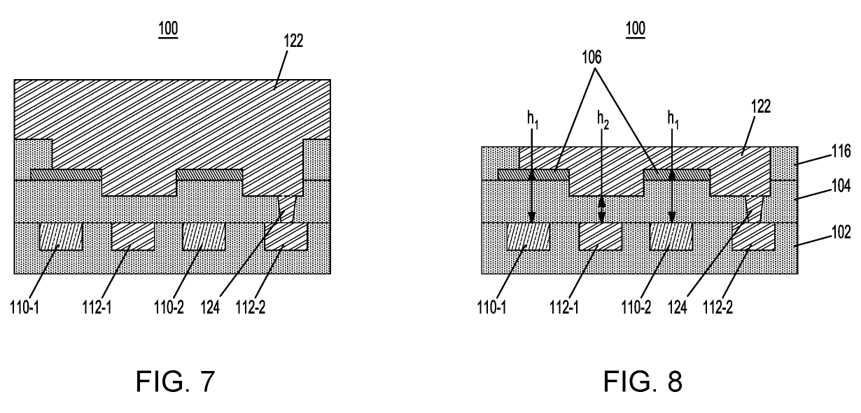

FIG. 7 shows a cross-sectional view of the interconnect structure 100 following a metallization process. A metallic liner (not shown) is formed on the surfaces exposed by the trench opening 600 and the via opening 602. The metallic liner can be formed using similar techniques and materials as described above for metal lines 112, for example. A conductive metal can then be deposited using a suitable deposition process such as ALD, PVD, CVD or electroplating to form the metal line 122 and the via 124. The conductive metal can include a similar material as the metal lines 112, for example.

FIG. 8 shows a cross-sectional view of the interconnect structure 100 following a planarization process, according to an illustrative embodiment. The planarization process (e.g., CMP) planarizes the interconnect structure 100 so that the top surface of the metal line 122 is level with the top surface of the ILD layer 116, as shown. According to an embodiment, the metal line 122 corresponds to a high-voltage domain, and the via 124 provides an electrical connection from the metal line 112-2 and the metal line 122.

Notably, the vertical spacing between the metal lines 110 and the metal line 122 is a first height (h₁) and the vertical spacing between the metal line 112-1 and the metal line 122 is a second height (h₂), where the first height (h₁) is greater than the second height (h₂). This variation of heights is specific and unique to the disclosed embodiments. Placement and/or positioning of the various masking layers described above is intended to produce the height variations illustrated in FIG. 8. Accordingly, the embodiments illustrated by the interconnect structure 100 explicitly contemplate increased spacing between high-voltage and low-voltage domains for consecutive metallization layers (e.g., the metallization layer corresponding to the metal line 122 and the metallization layer corresponding to the metal lines 112), while also allowing the height of the via 124 to be consistent with other vias for the high voltage domain in the same metallization layer. Additionally, it is noted that portions of the etch stop layer 106 remain after metallization.

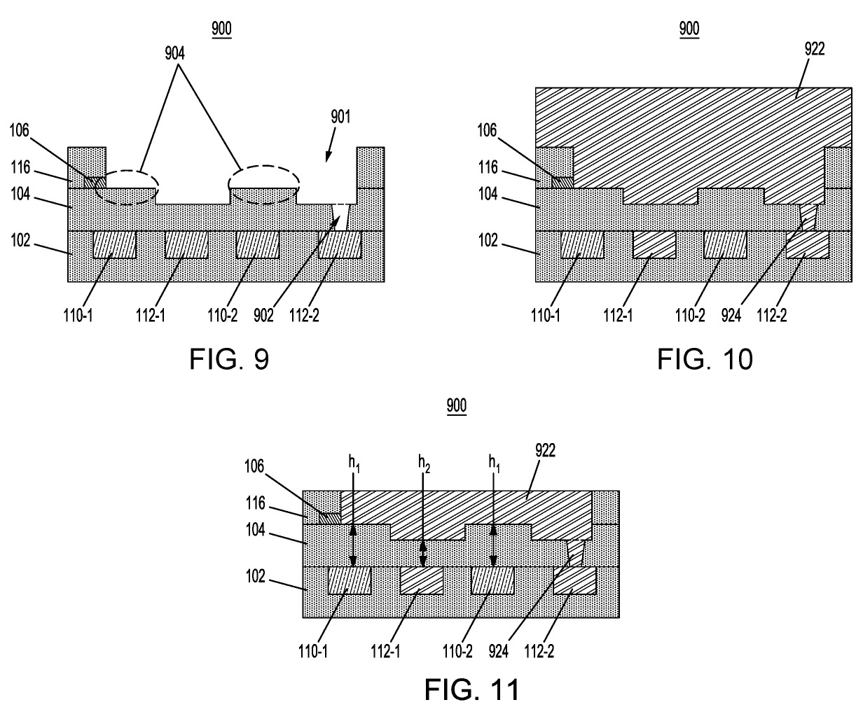

FIGS. 9-11 show cross-sectional views of an interconnect structure 900 in accordance with an alternative process that begins with the interconnect structure as shown in FIG. 5, according to an illustrative embodiment.

FIG. 9 shows a cross-sectional view of the interconnect structure 900 following an etching process that forms a trench opening 901 and a via opening 902. The etching process can be similar to that described for forming the trench opening 600 and via opening 602, but with removal of additional portions of the etch stop layer 106, as indicated by dashed circles 904. Removing the additional portions of the etch stop layer 106 can advantageously lower metal line capacitance and create a smoother metal line profile, for example.

The additional portions can be removed using one or more etching processes (e.g., a dry etching process, a wet chemical etching process, or a combination of these etching processes) and potentially one or more planarization processes during the formation of the via opening 602, for example. In some embodiments, a small portion of the etch stop layer 106 remains following the removal of the additional portions of the etch stop layer 106. For example, the small portion of the etch stop layer 106 can be adjacent to the trench opening 600 and within the ILD layer 116.

FIG. 10 shows a cross-sectional view of the interconnect structure 900 following formation of a metal line 922 and a via 924. The metal line 922 and the via 924 can be formed using materials and processes similar to those described for the metal line 122 and the via 124, for example.

FIG. 11 shows a cross-sectional view of the interconnect structure 900 following a planarization process, according to an illustrative embodiment. A planarization process (e.g., CMP) is performed to create a substantially flat surface, such that the top of the metal line 922 is coplanar with the top surface of the ILD layer 116, as shown.

Notably, the regions between the metal lines 110 and the metal line 122 of interconnect structure 100 are separated by the etch stop layer 106 and the ILD layer 104, whereas at least portions of the regions between the metal lines 110 and the metal line 922 in the interconnect structure 900 do not include the etch stop layer 106. The interconnect structure 900 advantageously provides lower metal line capacitance and a smoother metal line profile relative to interconnect structure 100, whereas the interconnect structure 100 can provide increased control over the depth of the metal line 122 relative to metal line 922.

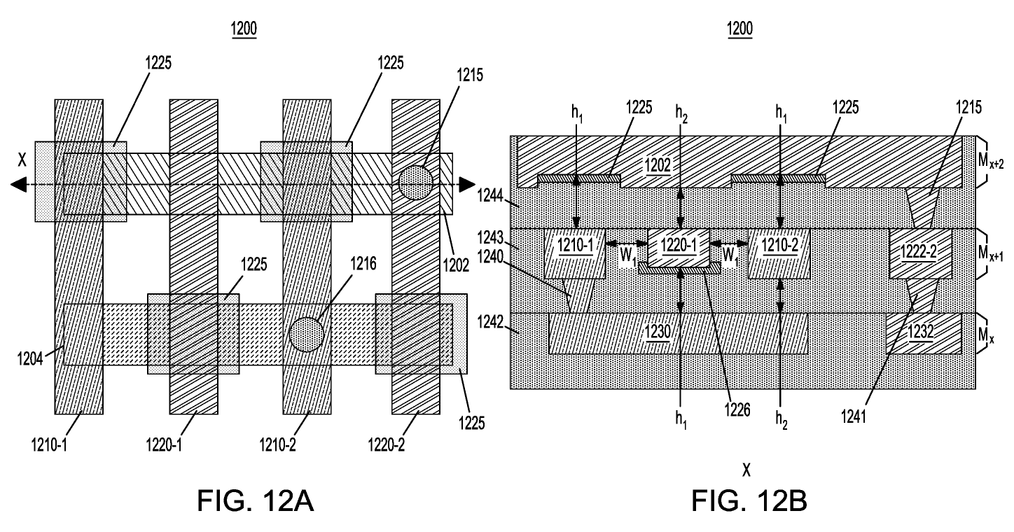

FIG. 12A depicts a top view of an interconnect structure 1200, indicating the cross-sectional location ‘X’ corresponding to the view shown in FIG. 12B. The interconnect structure 1200 includes a first metallization layer (Mₓ) with metal lines 1230 and 1232 formed within first ILD layer 1242, a second metallization layer (Mₓ₊₁) with metal lines 1210-1 and 1210-2 (collectively “metal lines 1210”) and 1220-1 and 1220-2 (collectively “metal lines 1220”) formed within a second ILD layer 1243, and a third metallization layer (Mₓ₊₂) with metal lines 1202 and 1204 formed within a third ILD layer 1244. For clarity, the top view of FIG. 12A illustrates only the first metallization layer and the second metallization layer. It is to be appreciated that in other embodiments, the interconnect structure 1200 may have one or more additional metallization layers depending on the application.

As described in more detail below, the vertical spacing between consecutive metallization layers of the interconnect structure 1200 can be controlled using similar techniques as described in conjunction with interconnect structure 100.

Vias 1215 and 1216 provide electrical connections between the second metallization layer and the third metallization layer, while vias 1240 and 1241 provide electrical connections between the first metallization layer and the second metallization layer. The metal lines 1202, 1220, 1232, along with the vias 1215 and 1241 are configured to operate within a first voltage domain (e.g., a high-voltage domain), while metal lines 1204, 1210, 1230 along with the vias 1216 and 1240 are configured to operate in a second voltage domain (e.g., a low-voltage domain).

The interconnect structure 1200 also includes etch stop layers positioned between intersecting areas of adjacent metallization layers. Specifically, an etch stop layer 1225 is positioned between the metal line 1210-1 and the metal line 1202, and between the metal line 1210-2 and the metal line 1202; and an etch stop layer 1226 is positioned between the metal line 1220-1 and the metal line 1230.

The etch stop layer 1225, the metal lines 1202 and 1220-2, and the via 1215 may be formed using similar materials and techniques as used for the etch stop layer 106, the metal lines 122 and 112-2, and the via 124. As with interconnect structure 100, the spacing between intersecting areas of consecutive metallization layers in the interconnect structure 1200 can be a first height (h₁), while the spacing in other areas can be a second height (h₂), where h₁ is greater than h₂. Notably, the via height remains consistent across voltage domains; for example, the via 1240 and the via 1241 may have a same height (h₂). Advantageously, this allows adjustment of both inter-layer and intra-layer spacing based on the difference in voltage between domains, thereby improving resistance to both intra-layer TDDB and inter-layer TDDB.

In other embodiments, the vertical spacing between at least some of the intersecting areas of consecutive metallization layers in the interconnect structure 1200 can be controlled using similar techniques as described in conjunction with interconnect structure 900. As an example, prior to forming metal line 1202 at least portions of the etch stop layer 1225 as described in conjunction with FIG. 9, and the metal line 1202 can be formed as described in conjunction with FIGS. 10-11. Alternatively, or additionally, at least portions of the etch stop layer 1226 can be removed to control the vertical spacing between the metal line 1230 and the metal line 1220-1 using techniques similar to those described for interconnect structure 900, for example.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, complementary metal-oxide-semiconductors (CMOSs), metal-oxide-semiconductor FETs (MOSFETs), and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

In one embodiment, a semiconductor structure includes a first set of interconnected metal lines and a second set of interconnected metal lines. The semiconductor structure includes a first metallization layer including a first metal line in the first set of interconnected metal lines and a second metal line in the second set of interconnected metal lines. The semiconductor structure further includes a second metallization layer including a third metal line in the second set of interconnected metal lines, where the third metal line is disposed above the first metal line and the second metal line, and where a spacing between the first metal line and the third metal line is greater than a spacing between the second metal line and the third metal line.

In embodiments, the semiconductor structure may further include an etch stop layer disposed between the first metal line and the second metal line.

In embodiments, the etch stop layer may include silicon nitride, silicon carbonitride, silicon carbide, aluminum nitride, aluminum oxide, aluminum oxynitride, titanium nitride, and/or silicon oxide.

In embodiments, the semiconductor structure may further include a first via connecting the second metal line to the third metal line.

In embodiments, the semiconductor structure may further include at least one second via disposed between the first metallization layer and the second metallization layer, where the at least one second via is substantially a same height as the at least one second via.

In embodiments, the first set of interconnected metal lines may be designated for a first voltage level and the second set of interconnected metal lines may be designated for a second voltage level that is different than the first voltage level.

In embodiments, the semiconductor structure may further include dielectric material that fill in areas corresponding to where the spacing between the first metal line and the third metal line is greater.

In embodiments, the semiconductor structure may further include one or more interlayer dielectric layers, where the second metallization layer and the first metallization layer are disposed within the one or more interlayer dielectric layers.

In another embodiment, a semiconductor structure includes a first set of interconnected metal lines and a second set of interconnected metal lines. The semiconductor structure includes a first metallization layer including a first metal line in the first set of interconnected metal lines and a second metal line in the second set of interconnected metal lines. The semiconductor structure includes a second metallization layer including a third metal line in the second set of interconnected metal lines, where the third metal line is disposed above the first metal line and the second metal line. The semiconductor structure further includes an interlayer dielectric layer positioned between the first metallization layer and the second metallization layer, where a first portion of the interlayer dielectric layer above the first metal line is thicker than a second portion of the interlayer dielectric layer above the second metal line.

In embodiments, the semiconductor structure may further include an etch stop layer disposed between the first metal line and the second metal line.

In embodiments, the etch stop layer may include silicon nitride, silicon carbonitride, silicon carbide, aluminum nitride, aluminum oxide, aluminum oxynitride, titanium nitride, and/or silicon oxide.

In embodiments, the first metallization layer may further include a fourth metal line. The first metal line and the second metal line may be laterally spaced by a first distance, and the second metal line and the fourth metal line may be laterally spaced by a second distance, where the first distance is substantially equal to the second distance.

In embodiments, the semiconductor structure may further include a via connecting the second metal line to the third metal line.

In yet another embodiment, a method includes forming a first metallization layer including a first metal line and a second metal line, depositing an etch stop layer over the first metallization layer, and selectively removing portions of the etch stop layer above the second metal line. The method further includes forming a second metallization layer including a third metal line, where a vertical spacing between the first metal line and the third metal line is greater than a vertical spacing between the second metal line and the third metal line, and where the first metal line corresponds to a first set of interconnected metal lines and the second metal line and third metal line correspond to a second set of interconnected metal lines.

In embodiments, the method may further include forming a first via connecting the second metal line to the third metal line.

In embodiments, the method may further include forming at least one second via between the first metallization layer and the second metallization layer, where the at least one second via is substantially a same height as the at least one second via.

In embodiments, the third metal line and the first via may be formed using a dual damascene process.

In embodiments, selectively removing the portions of the etch stop layer may include maintaining at least one other portion of the etch stop layer above the first metal line.

In embodiments, the etch stop layer may include silicon nitride, silicon carbonitride, silicon carbide, aluminum nitride, aluminum oxide, aluminum oxynitride, titanium nitride, and/or silicon oxide.

In embodiments, a bottom surface of the third metal line may extend below a bottom surface of the etch stop layer.

The above-described embodiments advantageously provide improved reliability and performance in semiconductor devices by addressing inter-layer TDDB risks while maintaining compatibility with advanced manufacturing processes.

Embodiments described herein can provide an interconnect structure that strategically varies vertical spacing between consecutive metallization layers above regions with metal lines operating at differing voltage domains (e.g., high-voltage domain and low-voltage domain). This approach can effectively mitigate inter-layer TDDB risks, thereby enhancing reliability and performance for semiconductor devices such as in high-voltage applications. Some embodiments also preserve consistent via height across voltage domains, which ensures seamless integration with existing fabrication processes without compromising scalability or yield.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times, and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a first set of interconnected metal lines;
a second set of interconnected metal lines;
a first metallization layer comprising a first metal line in the first set of interconnected metal lines and a second metal line in the second set of interconnected metal lines; and
a second metallization layer comprising a third metal line in the second set of interconnected metal lines, wherein the third metal line is disposed above the first metal line and the second metal line, and wherein a spacing between the first metal line and the third metal line is greater than a spacing between the second metal line and the third metal line.

2. The semiconductor structure of claim 1, further comprising:
an etch stop layer disposed between the first metal line and the second metal line.

3. The semiconductor structure of claim 2, wherein the etch stop layer comprises silicon nitride, silicon carbonitride, silicon carbide, aluminum nitride, aluminum oxide, aluminum oxynitride, titanium nitride, and/or silicon oxide.

4. The semiconductor structure of claim 1, further comprising:
a first via connecting the second metal line to the third metal line.

5. The semiconductor structure of claim 4, further comprising:
at least one second via disposed between the first metallization layer and the second metallization layer, wherein the at least one second via is substantially a same height as the at least one second via.

6. The semiconductor structure of claim 1, wherein the first set of interconnected metal lines is designated for a first voltage level and the second set of interconnected metal lines is designated for a second voltage level that is different than the first voltage level.

7. The semiconductor structure of claim 1, further comprising:
dielectric material that fill in areas corresponding to where the spacing between the first metal line and the third metal line is greater.

8. The semiconductor structure of claim 1, further comprising:
one or more interlayer dielectric layers, wherein the second metallization layer and the first metallization layer are disposed within the one or more interlayer dielectric layers.

9. A semiconductor structure, comprising:
a first set of interconnected metal lines;
a second set of interconnected metal lines;
a first metallization layer comprising a first metal line in the first set of interconnected metal lines and a second metal line in the second set of interconnected metal lines;
a second metallization layer comprising a third metal line in the second set of interconnected metal lines, wherein the third metal line is disposed above the first metal line and the second metal line; and
an interlayer dielectric layer positioned between the first metallization layer and the second metallization layer, wherein a first portion of the interlayer dielectric layer above the first metal line is thicker than a second portion of the interlayer dielectric layer above the second metal line.

10. The semiconductor structure of claim 9, further comprising:
an etch stop layer disposed between the first metal line and the second metal line.

11. The semiconductor structure of claim 10, wherein the etch stop layer comprises silicon nitride, silicon carbonitride, silicon carbide, aluminum nitride, aluminum oxide, aluminum oxynitride, titanium nitride, and/or silicon oxide.

12. The semiconductor structure of claim 9, wherein the first metallization layer further comprises a fourth metal line, and wherein:
the first metal line and the second metal line are laterally spaced by a first distance; and
the second metal line and the fourth metal line are laterally spaced by a second distance, wherein the first distance is substantially equal to the second distance.

13. The semiconductor structure of claim 9, further comprising:
a via connecting the second metal line to the third metal line.

14. A method, comprising:
forming a first metallization layer comprising a first metal line and a second metal line;
depositing an etch stop layer over the first metallization layer;
selectively removing portions of the etch stop layer above the second metal line; and
forming a second metallization layer comprising a third metal line, wherein a vertical spacing between the first metal line and the third metal line is greater than a vertical spacing between the second metal line and the third metal line, and wherein the first metal line corresponds to a first set of interconnected metal lines and the second metal line and third metal line correspond to a second set of interconnected metal lines.

15. The method of claim 14, further comprising:
forming a first via connecting the second metal line to the third metal line.

16. The method of claim 15, further comprising:
forming at least one second via between the first metallization layer and the second metallization layer, wherein the at least one second via is substantially a same height as the at least one second via.

17. The method of claim 15, wherein the third metal line and the first via are formed using a dual damascene process.

18. The method of claim 14, wherein the selectively removing comprises:
maintaining at least one other portion of the etch stop layer above the first metal line.

19. The method of claim 14, wherein the etch stop layer comprises silicon nitride, silicon carbonitride, silicon carbide, aluminum nitride, aluminum oxide, aluminum oxynitride, titanium nitride, and/or silicon oxide.

20. The method of claim 14, wherein a bottom surface of the third metal line extends below a bottom surface of the etch stop layer.
